(19) United States
(12) Patent Application Publication
(10) Pub. No.: US 2025/0209239 A1
(43) Pub. Date: Jun. 26, 2025

(54) METHOD AND SYSTEM FOR FORECASTING CELL STRUCTURE STATE

(71) Applicant: CellVoyant Technologies Limited, Bristol (GB)

(72) Inventors: Saad Mohammad, Bristol (GB); Rickard Sjögren, Bristol (GB); Edward Ren, Bristol (GB); Rafael Edgardo Carazo Salas, Bristol (GB); Elisa Pedone, Bristol (GB)

(21) Appl. No.: 18/989,387

(22) Filed: Dec. 20, 2024

Related U.S. Application Data
(60) Provisional application No. 63/613,921, filed on Dec. 22, 2023.

(51) Int. Cl. G06F 30/27; G06V 10/764; G06V 10/82; G06V 20/69

(52) U.S. Cl. CPC G06F 30/27; G06V 10/764; G06V 10/82; G06V 20/693; G06V 20/698; G06V 2201/03

(57) ABSTRACT

Provided herein are methods and computing systems for predicting a future state of a cell culture based on a current state of a cell culture.

### CROSS REFERENCE TO RELATED APPLICATION

This application claims priority to U.S. Provisional Application 63/613,921, filed Dec. 22, 2023, the disclosure of which is herein incorporated by reference in its entirety.

### FIELD OF THE DISCLOSURE

The present disclosure relates generally to methods and systems for predicting a future cell culture state based on a current state of the cell culture.

### BACKGROUND OF THE DISCLOSURE

Stem cell differentiation efficiency exhibits a notable degree of inconsistency among different cell lines and donors. For instance, gene expression differs between lines. This inconsistency has prompted researchers to assess the shortcomings of traditional static differentiation protocols, which often yield suboptimal results due to their inherent inflexibility.

To address this issue, there is growing interest in the concept of dynamic differentiation protocols. These protocols, in theory, involve the adjustment of timings and concentrations of added growth factors based on the current state of a cell culture. This may lead to improved outcomes, although the exact efficacy remains uncertain.

The inventors have discovered that a key challenge in implementing dynamic protocols lies in the need to forecast outcomes of various scenarios accurately. The inventors have further discovered that a goal is to determine how changes in protocol parameters, such as timings and concentrations, may impact the course of stem cell differentiation. Accurate forecasting could enable the selection of more suitable differentiation strategies.

### SUMMARY OF THE DISCLOSURE

The disclosure provides an effective and reliable method and system for forecasting a future state of a cell culture undergoing differentiation based on the current state, for example, as observed using live cell imaging. The method and system comprise building and training a machine learning model based on one or more images and optionally one or more protocol actions to predict the proportions of cell subpopulations at different future time points. The method and system further comprise using the trained machine learning model to predict the cell culture state at any future time point.

In non-limiting embodiments of the disclosure, methods of predicting the future state of a cell culture based on a current state of the cell culture are provided. The methods comprise: (a) receiving, by one or more processors, a request for a yield of a target cell type at a specific time in the future; (b) receiving, by the one or more processors, one or more images of a cell culture of the target cell type, wherein each of the one or more images include discrete image frames of the cell culture captured in real-time by an image pickup device; (c) providing, by the one or more processors, the one or more images of the cell culture to a machine learning system; (d) generating, by the machine learning system, a mathematical representation of each of the one or more images of the cell culture; (e) aggregating, by the machine learning system, temporal information based on the mathematical representation of each of the one or more images of the cell culture to generate spatio-temporal information; (f) predicting, by the machine learning system, the yield of the target cell type at the specific time in the future based on the spatio-temporal information; and (g) sending, by the one or more processors, the yield of the target cell type at the specific time to a communication device, wherein the communication device is configured to render the target cell type at the specific time on an output device.

In certain non-limiting embodiments, the methods further comprise: (b) receiving, by one or more processors, an input of one or more protocol actions for the cell culture; (c) providing, by the one or more processors, the input of the one or more protocol actions for the cell culture to a machine learning system; (d) generating, by the machine learning system, a mathematical representation of the one or more protocol actions in combination with the one or more images of the cell culture; (e) aggregating, by the machine learning system, temporal information based on the mathematical representation of the one or more protocol actions in combination with the one or more images of the cell culture to generate spatio-temporal information; (f) predicting, by the machine learning system, the yield of the target cell type at the specific time in the future based on the spatio-temporal information; and (g) sending, by the one or more processors, the yield of the target cell type at the specific time to a communication device, wherein the communication device is configured to render the target cell type at the specific time on an output device.

In non-limiting embodiments of the disclosure, computing systems for predicting a future state of a cell culture based on a current state of the cell culture are provided. The computing systems can, for example, comprise: (a) a receiver configured to receive from a communication device a request for a yield of a target cell type at a specific time in the future; (b) one or more processors configured to receive one or more images of a cell culture of the target cell type, wherein each of the one or more images include discrete image frames of the cell culture captured in real-time by an image pickup device; (c) a machine learning system configured to receive the one or more images of the cell culture to a machine learning system, generate a mathematical representation of each of the one or more images of the cell culture, aggregate temporal information based on the mathematical representation of each of the one or more images of the cell culture to generate spatio-temporal information, and predict the yield of the target cell type at the specific time in the future based on the spatio-temporal information; and a transmitter configured to send the yield of the target cell type at the specific time to a communication device.

In certain embodiments, the machine learning system comprises: an encoder configured to generate the mathematical representation of each of the one or more images of the cell culture; a translator configured to take the mathematical representation of each of the one or more images of the cell culture and create spatio-temporal information for the cell culture; and a predictor configured to take the spatio-temporal information and predict the yield of the target cell type at the specific time in the future based on the spatio-temporal information.

In certain embodiments, the machine learning system comprises an artificial neural network. In certain embodiments, the machine learning system comprises a convolutional neural network (CNN). In certain embodiments, the machine learning system comprises a transformer neural network (TNN).

In further non-limiting embodiments of the disclosure, a non-transitory computer readable storage medium is provided containing computer program instructions that, when executed by one or more processors, cause the one or more processors to perform operations comprising: (a) receiving, by the one or more processors, a request for a yield of a target cell type at a specific time in the future; (b) receiving, by the one or more processors, one or more images of a cell culture of the target cell type, wherein each of the one or more images include discrete image frames of the cell culture captured in real-time by an image pickup device; (c) providing, by the one or more processors, the one or more images of the cell culture to a machine learning system; (d) generating, by the machine learning system, a mathematical representation of each of the one or more images of the cell culture; (e) aggregating, by the machine learning system, temporal information based on the mathematical representation of each of the one or more images of the cell culture to generate spatio-temporal information; (f) predicting, by the machine learning system, the yield of the target cell type at the specific time in the future based on the spatio-temporal information; and (g) sending, by the one or more processors, the yield of the target cell type at the specific time to a communication device, wherein the communication device is configured to render the target cell type at the specific time on an output device.

In certain embodiments, the cell culture comprises a stem cell culture. The stem cell culture can, for example, comprise an embryonic stem cell culture, an adult stem cell culture, an induced pluripotent stem cell culture, or a trophoblast stem cell culture. In certain embodiments, the stem cell culture comprises a mesenchymal stem cell culture, a hematopoietic stem cell culture, a neural stem cell culture, an epithelial stem cell culture, or a cord blood stem cell culture.

In certain embodiments, the stem cell culture is undergoing a differentiation process. The stem cell culture undergoing a differentiation process can, for example, comprise progenitor cells. The progenitor cells can, for example, be selected from, but not limited to, mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells.

In certain embodiments, the differentiation process results in the stem cell culture differentiating to a mesoderm, endoderm, and/or ectoderm. The mesoderm can, for example, comprise a skeletal muscle cell, a kidney cell, a red blood cell, or a smooth muscle cell. The endoderm can, for example, comprise a lung cell, a thyroid cell, or a pancreatic cell. The ectoderm can, for example, comprise a skin cell, a neuron cell, or a pigment cell.

In certain embodiments, predicting the future state of a cell culture can, for example, comprise predicting the growth of the cells, predicting the total amount of cells, and/or predicting the composition of subpopulations of cells in the cell culture.

In certain embodiments, predicting the future state of a cell culture comprises predicting the state of the cell culture at the next time point an image is captured, at the next two time points an image is captured, and/or at any time point an image is captured.

Additional features, advantages, and embodiments of the disclosure may be set forth or apparent from consideration of the detailed description and drawings. Moreover, it is to be understood that the foregoing summary of the disclosure and the following detailed description and drawings provide non-limiting examples that are intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and the various ways in which it may be practiced.

FIG. 1 shows a block diagram of a system for forecasting a cell culture state at one or more points in time.

FIG. 2 shows a semantic overview of an aspect of a machine learning system included in an embodiment of a predictive processing system, included in the system in FIG. 1.

FIG. 3 shows an embodiment of a machine learning model architecture, including components and their interconnections, as well as each component's inputs and outputs.

FIG. 4 shows certain components that can be included in the embodiment of the machine learning model architecture in FIG. 3.

FIG. 5 shows a block diagram of an embodiment of the predictive processing system.

FIG. 6 shows a training process for building and training a machine learning system in the predictive processing system.

FIG. 7 shows a schematic detailing the training and inference according to the training process in FIG. 6.

FIG. 8 shows a forecasting process for predicting a yield for different differentiations at any point in time.

FIG. 9 shows a graph demonstrating an average error in relation to input frames, with a smoothing window of size 5 applied for enhanced clarity.

FIG. 10 shows a graph demonstrating the average error in related to querying delta frames, with a smoothing window of size 5 applied for enhanced clarity.

FIG. 11 shows various examples of a predicted yield for two different differentiations by the predictive processing system.

The present disclosure is further described in the detailed description that follows.

### DETAILED DESCRIPTION OF THE DISCLOSURE

The disclosure and its various features and advantageous details are explained more fully with reference to the non-limiting embodiments and examples that are described or illustrated in the accompanying drawings and detailed in the following description. It should be noted that features illustrated in the drawings are not necessarily drawn to scale, and features of one embodiment can be employed with other embodiments as those skilled in the art would recognize, even if not explicitly stated. Descriptions of well-known components and processing techniques may be omitted so as to not unnecessarily obscure the embodiments of the disclosure. The examples are intended merely to facilitate an understanding of ways in which the disclosure can be practiced and to further enable those skilled in the art to practice the embodiments of the disclosure. Accordingly, the examples and embodiments should not be construed as limiting the scope of the disclosure. Moreover, it is noted that like reference numerals represent similar parts throughout the several views of the drawings.

An approach to reduce variability among cell culture systems (such as, for example, stem cell culture systems undergoing differentiation) includes purifying target or progenitor cells from other cell types. This has for instance been done in neural progenitor cells and foregut endoderm cells. This approach introduces additional complexity in the protocol by needing an explicit purification stage. Implementing purification correctly requires method development on its own.

Another approach is to use live cell imaging and machine learning. This approach provides a set of specialized machine learning models and needs additional method development for each new use case.

A further approach involves directly controlling the gene expression of certain genes based on fluorescence readout. This approach has been demonstrated for both maintaining embryonic stem cell culture as well as improving differentiation. The approach, however, relies on being able to directly measure gene expression of key genes by using genetically engineered cells and is therefore not easily scalable to new use cases.

The disclosure provides a technology solution for forecasting a future state of a stem cell differentiation process based on a sequence of observations of the process. In various embodiments, a cell culture is monitored using live cell imaging and growth and changes in composition of cellular subpopulations through time are forecasted by the technology. The technology predicts the absolute yields of various fates at a specified future time by analyzing a streaming time-lapse sequence of cell images. Absolute yield can be defined as the number of cells of a certain cell type or fate, such as, for example, endoderm cells. Given an arbitrary querying future time as input—the time for which the forecast is desired—the technology produces forecasts of the absolute yields for that time point.

Provided herein is a method of building, training, testing, and implementing a machine learning system, preferably an artificial neural network, comprising one or more machine learning models. In an embodiment, the machine learning system comprises: (1) an encoder that is responsible for creating a mathematical representation of one or more cellular images as an input; (2) a translator, which takes the sequence of the one or more cellular image representations over time as an input and aggregates the temporal information based on the mathematical representation of the one or more cellular images to generate spatio-temporal information; and (3) a predictor, which takes the spatio-temporal information and an arbitrary, specified future time point as a query input and predicts the absolute yield of the target cell types at the queried time point. The queried time point can include, for example, a date and time (for example, 03042024:2312 for Apr. 3, 2024, at 11:12 PM) or a period of time (for example, a specified number of minutes, hours, days, months, or years).

In various embodiments, a machine learning model is built and trained on a sequence of microscopic images of cell cultures, where the target cell type yields are known for one or more time points of an experiment. Using the trained machine learning model (for example, in a new experiment) can allow for the prediction of the future absolute yield based on a sequence of microscopic images of the cell culture acquired at current and preceding time points.

Additionally, the machine learning model can take the sequence of protocol conditions, also referred to as protocol actions, as an input and can predict the future absolute yield at the query time point conditioned on the protocol actions.

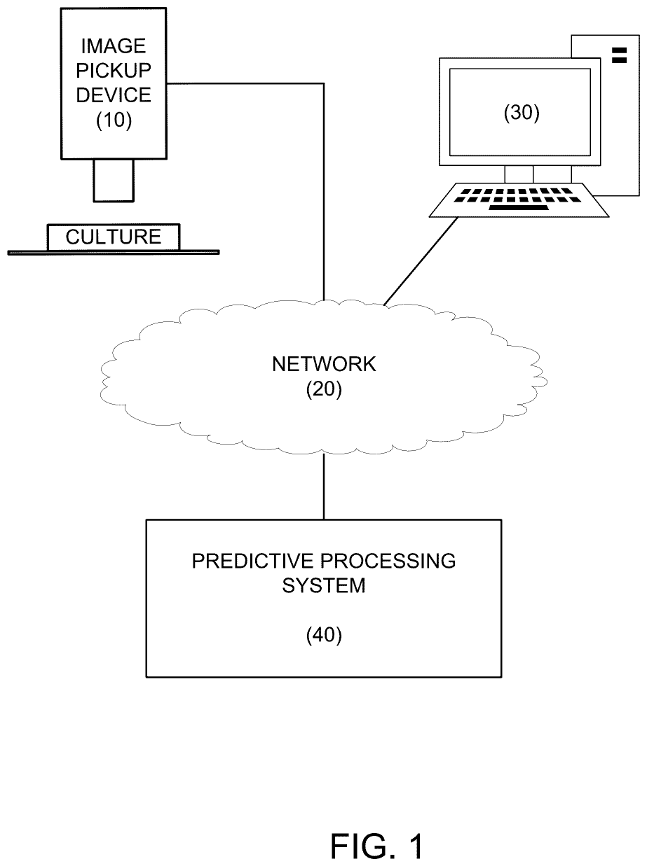

FIG. 1 shows a block diagram of a system for forecasting a cell culture state at one or more points in time. The system includes an image pickup device 10, a network 20, a communicating device 30, and a predictive processing system 40. In various embodiments, the image pickup device 10 includes a two-dimensional (2D) or three-dimensional digital image pickup device, such as, for example, a digital microscope camera, an electron microscope, or other high or ultrahigh resolution microscopic image pickup device (such as, for example, 1.5, 5, 10, 12, or 18 megapixels, or greater). The image pickup device 10 is configured to capture and store microscopic images of a target, such as, for example, a cell culture. The image pickup device 10 is further configured to send the microscopic images to the communicating device 10 or predictive processing system 40 via one or more communication links, which can include one or more communication links on the network 20.

In an embodiment, the communicating device 30 is configured to render (for example, display) one or more of the microscopic images on a display device. The communicating device 30 is further configured to receive annotations for each feature in each microscopic image, including, for example, a label and description for each feature. In this regard, the communicating device 30 includes a microscopic image annotation and inference (MIA&I) system. Alternatively, the MIA&I system is contained in the predictive processing system 40 and accessed and interacted with by the communicating device 30 via a communication link.

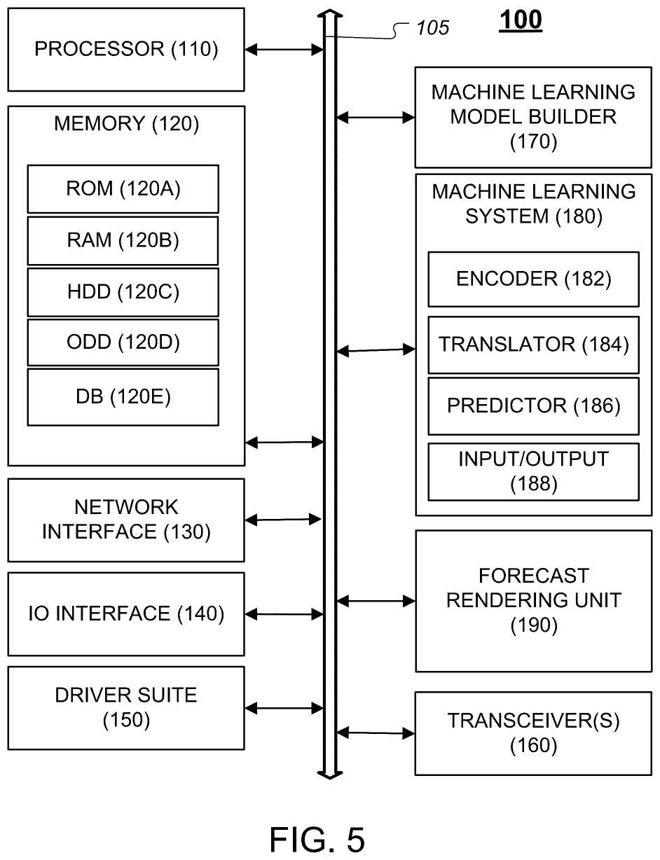

In various embodiments, the MIA&I system can be configured to use a transductive learning methodology to automatically infer labels of unlabeled cells based on expert inputs. The MIA&I system is configured to analyze 2D/3D microscopic images using segmentation, registration, or annotation. In a non-limiting embodiment, the MIA&I system can be contained in a machine learning system 180 (shown in FIG. 5), which is discussed below.

The predictive processing system 40 is configured to monitor and analyze, in real-time, a series of live microscopic images of a particular target cell culture and forecast the future state of the cell culture undergoing differentiation based on the current state of the target cell culture. In various embodiments, the predictive processing system 40 is configured to train a machine learning model based on one or more microscopic images to predict the proportions of cell subpopulations at different future time points in the target cell culture. The predictive processing system 40 is further configured to, by means of the trained machine learning model, predict any future time point for the target cell culture.

In an embodiment of the system in FIG. 1, the predictive processing system 40 is configured to receive (for example, via one or more communication links) one or more microscopic images (for example, from the image pickup device 10) and monitor growth and changes in composition of cellular subpopulations in real-time (or near real-time). The predictive processing system 40 can monitor the growth and changes in composition of cellular subpopulations in the target cell culture through time and predict an absolute yield of various fates at a specified future time by analyzing a streaming time-lapse sequence of the microscopic images. The absolute yield can include the number of cells of a certain cell type, or fate, such as, for example, endoderm cells.

The predictive processing system 40 can receive a forecast query from the communicating device 30, or an input device (not shown), containing a specific time for which a forecast is desired. The predictive processing system 40 can process the forecast query and, based on an analysis of the microscopic images, produce forecasts of the absolute yield for the time point specified in the forecast query.

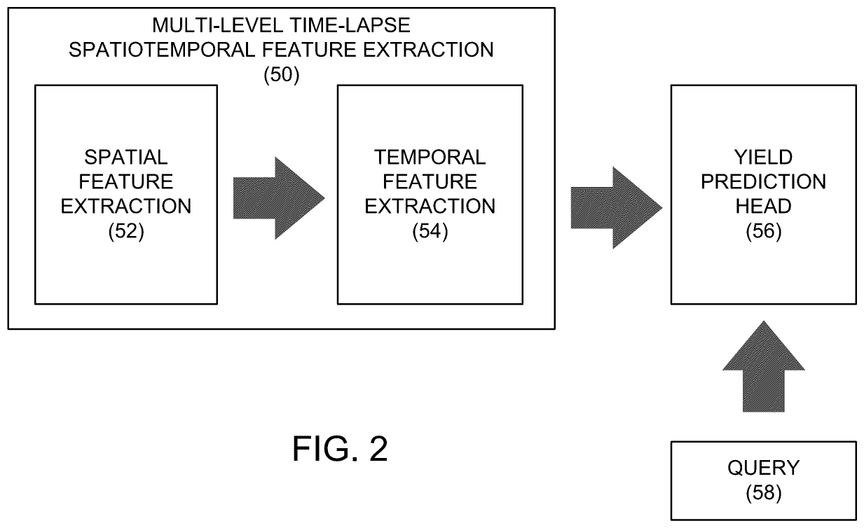

FIG. 2 shows a semantic overview of an aspect of a machine learning system contained in the predictive processing system 40. In an embodiment, the predictive processing system 40 can include a predictive processor 100 (shown in FIG. 5) that includes a machine learning system 180 comprising an encoder 182, a translator 184, and a predictor 186. Referring to FIG. 2, the encoder 182 and translator 184 can be configured to perform multilevel time-lapse spatio-temporal feature extractions, with the encoder 182 performing spatial feature extraction and the translator 184 performing temporal feature extraction. The predictor 186 can be configured to predict an absolute yield for each fate at a queried time.

Referring to FIG. 5, in the depicted embodiment of the predictive processor 100: the encoder 182 can be configured to receive as input each microscopic image and create a mathematical representation of the microscopic image; the translator 184 can be configured to receive as input the mathematical representations for each of a sequence of microscopic images and aggregate and generate spatio-temporal information for the sequence of images; and the predictor 186 can be configured to receive as input the spatio-temporal information and a forecast query (for example, from the communicating device 30 or another input device) containing a specified, future time point, and generate a yield forecast that includes a predicted yield of a target cell type at the specified time point. The yield forecast can include the predicted yield at the specified time point and a prediction score, which can be, for example, a percentage value or other scoring value. The percentage value can be, for example, between 0% and 100%, with 0% indicating no likelihood of the predicted yield occurring at the specified time point, and 100% indicating certainty that the predicted yield will occur at the specified time point. representations

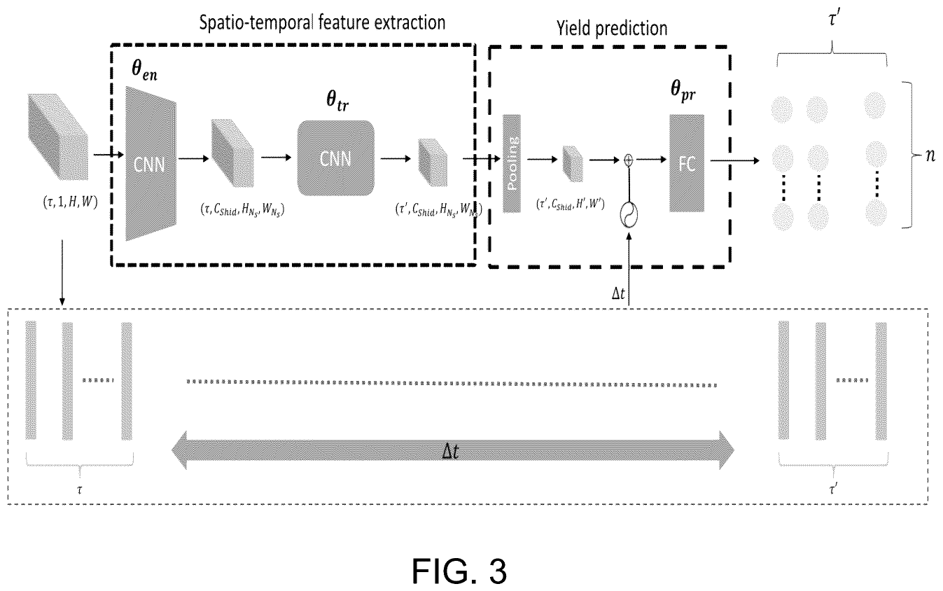

FIG. 3 shows an embodiment of a machine learning model architecture included in the predictive processor 100 (shown in FIG. 5), including components and their interconnections, as well as each component's inputs and outputs. In the embodiment, the model architecture has three components, corresponding interconnections, and each component's inputs and outputs. The encoder takes a sequence of input microscopic image frames, convolves each along its spatial dimensions to extract spatial features, and passes it on to the translator. The translator then convolves it along its temporal dimension, extracting the temporal evolution, which is finally fed to a predictor along with the encoded querying input Δt, to predict the target yield at the given time.

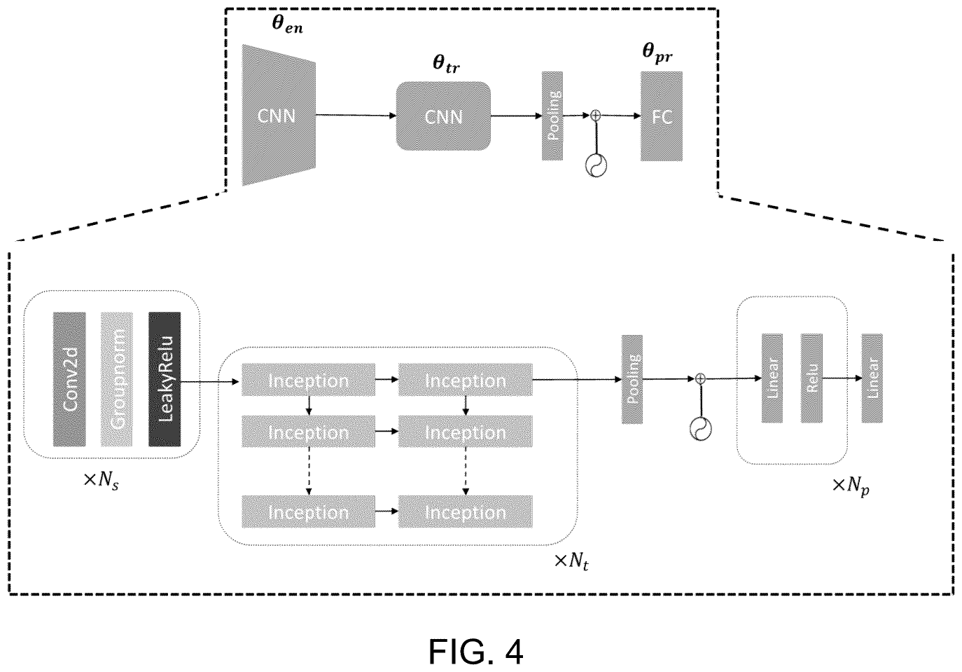

FIG. 4 shows certain components that can be included in the embodiment of the machine learning model architecture in FIG. 3. For instance, the encoder can stack Ns ConvNormReLU layers, and the translator can employ Nt Inception modules. A pooling layer can be provided along spatial dimensions of the extracted features, followed by the predictor utilizing Np LinearReLU layers, and then a final Linear layer for yield predictions.

Referring to FIGS. 3-5, in the machine learning system 180, the encoder 182 and translator 184 can each include a convolutional neural network (CNN), with the first CNN being configured to receive a time-lapse sequence of microscopic images Iₜ of a target cell culture (i.e., I_{t1:t2}={Iₜ₁, Iₜ₁₊₁, . . . . Iₜ₂}, with t1<t2) in a time window starting at t1 and ending at t2, where Iₜ represents the microscopic image of the cells captured at time t, of width W and height H. Querying time, denoted by q∈(0,T], denotes the time at which to forecast the per-fate cell yields, where T is the time length of the experiment, and aspects of the machine learning system can be represented as mapping function ƒ_{θ} governed by parameter θ, which takes as input τ number of frames I_{t-τ:t} and querying time q∈[t,T] and outputs forecasted yields in future time interval of length τ′ for n different cell fates y_{q:q+τ′} such that y_{q}=(y_{q1}, y_{q2}, . . . y_{qn}). Thus, a forecast can be presented as ƒ_{θ}: N^{τ×W×H}×(0,T]→N^{τ′×n}. In the alternative where actions are included, the sequence of k possible actions at past τ timepoints, the current time point, and each of the τ′ future timesteps can be added as input to the machine learning system as ƒ_{θ}: N^{τ×(k×(τ+τ′))×W×H}×(0,T]→N^{τ′×n}.

In an embodiment, the machine learning system can include a machine learning model based on SimVP, but with some key differences. SimVP, which is discussed in the article by Z. Gao, C. Tan, L. Wu, and S. Z. Li, titled “Sim VP: Simpler yet better video prediction,” in Proceedings of the IEEE/CVF Conference on Computer Vision and Pattern Recognition, 2022, pp. 3170-3180, is designed for short-term future video frame prediction at a fixed Δt. In contrast, the machine learning model herein is purposed for long-term integer number prediction at given querying time. In this regard, the predictor 182 includes temporal positional encoding, effectively enhancing the machine learning model for the use cases contemplated by this disclosure.

In the embodiment depicted in FIG. 5, the machine learning system 180 includes the encoder 182, translator 184, and predictor 186, wherein the encoder 182 can extract spatial features, then the translator 184 can extract the temporal evolution by transforming extracted spatial features into spatio-temporal ones, and, finally, the predictor 186 can use the spatio-temporal information along with querying time input to predict future frames yields. Hence, parameters in the machine learning system 180 can be split into encoder, translator, and predictor parameters, θ={θₑₙ, θₜᵣ, θₚᵣ}. The training process for machine learning system 180 involves optimizing these parameters to minimize the expected disparity between the forecasted yield of the machine learning model, achieved through mapping by ƒ_{θ}, and the actual yield. This optimization is carried out across various frame times, ensuring accuracy in predictions for any querying time within a specified interval. FIGS. 3 and 4 depict semantic overviews of the machine learning model architecture.

FIG. 5 shows a block diagram of an embodiment of the predictive processor 100. The predictive processor 100 includes a bus 105, one or more processors 110, a storage 120, a network interface 130, an input-output (IO) interface 140, a driver suite 150, one or more transceivers 160, a machine learning model builder 170, the machine learning system 180, and a forecast rendering unit 190. The bus 105 which can be connected to any or all of the components 110 to 190 by one or more communication links.

Any one or more of the components 110 to 190 can include a computing resource or a computing device. One or more of the components 130 to 150 or 170 to 190 can include a computing resource or computing device that is separate from the processor(s) 110, as seen in FIG. 5, or integrated with the processor(s) 110. In certain embodiments, the components 130 to 150 or 170 to 190 can include a computer resource that can be executed on the processor(s) 110 as one or more processes. The computer resources can be contained in the storage 120.

The bus 105 can include any of several types of bus structures that can further interconnect to a memory bus (with or without a memory controller), a peripheral bus, and a local bus using any of a variety of commercially available bus architectures.

The processor 110 can include any of various commercially available processors, including for example, a central processing unit (CPU), a graphic processing unit (GPU), a general-purpose GPU (GPGPU), a dedicated neural processing unit (NPU), a tensor processing unit (TPU), a field programmable gate array (FGPA), an application-specific integrated circuit (ASIC), a system-on-a-chip (SOC), a single-board computer (SBC), a manycore processor, multiple microprocessors, or any other computing device architecture. The processor 110 can be arranged to interact with any of the components 120 to 190 to carry out or facilitate the processes included, described or contemplated by this disclosure. The processor 110 can be arranged to run one or more machine or deep learning systems.

The processor 110 can be arranged to run an operating system (OS), which can include an operating system (OS) kernel that can control all operations on the PP system 100. The OS kernel can include, for example, a monolithic kernel or a microkernel. The OS kernel can be arranged to execute on the processor 110 and have control over operations in the processor 110.

The OS or OS kernel can be contained in the storage 120 and executed by the processor 110. The OS or OS kernel can be cached in the storage 120, such as, for example, in a random-access memory (RAM). The OS kernel can represent the highest level of privilege on the OS or the processor 110. The OS can include a driver for each hardware device with which the processor 110 might interact, including, for example, the transceivers 160. The OS kernel can be arranged to allocate resources or services to, and enable computing resources or processes to share or exchange information, protect the resources or services of each computing resource or process from other computing resources or processes, or enable synchronization amongst the computing resources or processes.

The OS kernel can, when a process is triggered, initiate and carry out the process for that computer resource, including allocating resources for the process, such as, for example, hard disk space, memory space, processing time or space, or other services on one or more hardware devices, including, for example, the transceiver 160. The OS kernel can carry out the process by allocating memory space and processing resources to the process, loading the corresponding computing resource (or portion of a computing resource) into the allocated memory space, executing instructions of the computing resource on the OS kernel, or interfacing the process to one or more computer resources or processes.

The OS kernel can be arranged to facilitate interactions between the computing resources or processes. The processor 110, which runs the OS, can be arranged to arbitrate access to services and resources by the processes, including, for example, running time on the processor 110. The OS kernel can be arranged to take responsibility for deciding at any time which of one or more processes should be allocated to any of the resources.

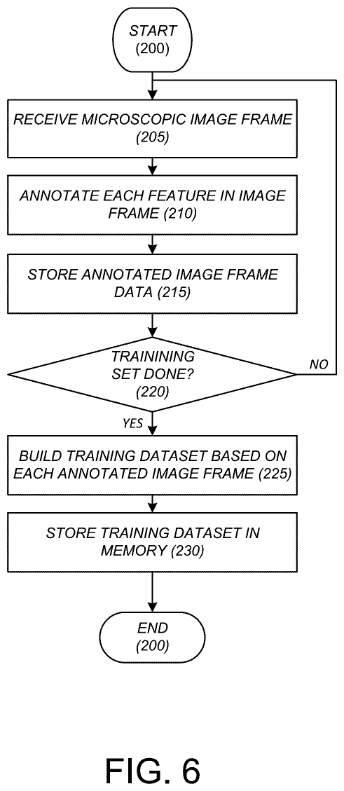

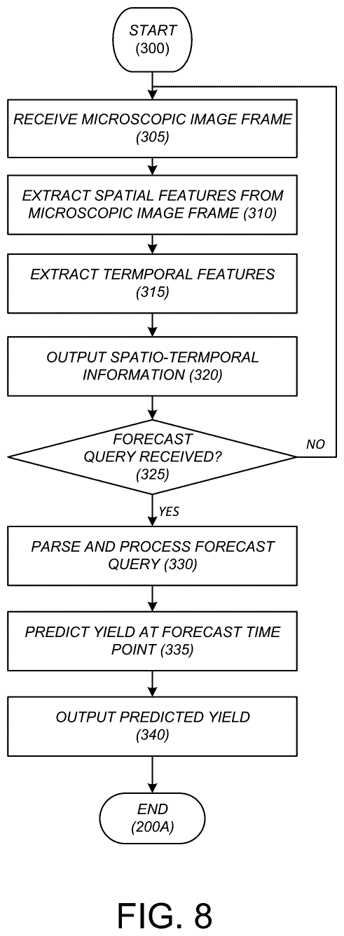

The predictive processor 100 can include a non-transitory computer-readable storage medium that can hold executable or interpretable computer resources, including computer program code or instructions that, when executed by the processor 110, cause the steps, processes or methods in this disclosure to be carried out, including the machine learning model training process 200 (shown in FIG. 6) and the yield predicting process 300 (shown in FIG. 8). The computer-readable storage medium can be contained in the storage 120 or an external storage device (not shown).

The storage 120 can include a read-only memory (ROM) 120A, a random-access memory (RAM) 120B, a hard disk drive (HDD) 120C, an optical disk drive (ODD) 120D, and a database (DB) 120E. The storage 120 can provide nonvolatile storage of data, data structures, and computer-executable instructions, and can accommodate the storage of any data in a suitable digital format.

The storage 120 can include the non-transitory computer-readable medium that can hold the computer resources (including code or instructions) that can be executed (run) or interpreted by the operating system on the processor 110. The computer-readable medium can be contained in the HDD 120C.

A basic input-output system (BIOS) can be stored in the non-volatile memory in the storage 120, which can include, for example, a ROM, an erasable programmable read-only memory (EPROM), or an electrically erasable programmable read-only memory (EEPROM). The BIOS can contain the basic routines that help to transfer information between any one or more of the components 110 to 190 in the system 100, such as during start-up.

The RAM 120B can include a dynamic random-access memory (DRAM), a synchronous dynamic random-access memory (SDRAM), a static random-access memory (SRAM), a non-volatile random-access memory (NVRAM), or another high-speed RAM for caching data.

The HDD 120C can include, for example, an enhanced integrated drive electronics (EIDE) drive, a serial advanced technology attachments (SATA) drive, or any suitable hard disk drive for use with big data. The HDD can be configured for external use in a suitable chassis (not shown). The HDD can be arranged to connect to the bus B via a hard disk drive interface (not shown). In various nonlimiting embodiments, the HDD 120C can include the machine learning model builder 170, the machine learning system 180, or the forecast rendering unit 190.

The DB 120E can be arranged to be accessed by any one or more of the components in the system 100. The DB 120E can be arranged to receive a query and, in response, retrieve specific data, data records or portions of data records based on the query. A data record can include, for example, a file or a log. The DB 120E can include a database management system (DBMS) that can interact with the components 110 to 190. The DBMS can include, for example, SQL, NoSQL, MySQL, Oracle, Postgress, Access, or Unix. The DB 120E can include a relational database.

The DB 120E can be arranged to contain machine learning training datasets, testing datasets, and historical data. The DB 120E can contain information related to each cell culture and cell type.

Any number of computer resources can be stored in the storage 120, including, for example, a program module, an operating system (not shown), one or more application programs (not shown), or program data (not shown). Any (or all) of the operating system, application programs, program modules, and program data can be cached in the RAM as executable sections of computer code.

The network interface 130 can connect to the network 20 (shown in FIG. 1). The network interface 130 can be arranged to communicate with any number of devices (such as, for example, the image pickup device 10 or the communication device 30, shown in FIG. 1), either directly or via the network 20 over one or more communication links. The network interface 130 can include a wired or wireless communication network interface (not shown) or a wired or wireless modem (not shown). When used in a local area network (LAN), the network interface 130 can connect to the LAN network through the communication network interface; and, when used in a wide area network (WAN), it can connect to the WAN network through the modem. The modem (not shown) can be connected to the system bus 105 via, for example, a serial port interface (not shown). The network interface 130 can be arranged to interact with the transceiver 160, or it can include a receiver (not shown), transmitter (not shown) or transceiver (not shown).

The input-output (IO) interface 140 can receive instructions or data from an operator via a user interface (not shown), such as, for example, a keyboard (not shown), a mouse (not shown), a pointer (not shown), a stylus (not shown), a microphone (not shown), an interactive voice response (IVR) unit (not shown), a speaker (not shown), or a display device (not shown). The received instructions and data can be forwarded from the IO interface 140 as signals via the bus 105 to any component in the system 100.

The driver suite 150 can include an audio driver, a video driver, or other driver necessary to carry out the operations described herein. The audio driver can include a sound card, a sound driver (not shown), an interactive voice response (IVR) unit, or any other device necessary to render a sound signal on a sound production device (not shown), such as for example, a speaker (not shown). The video driver can include a video card (not shown), a graphics driver (not shown), a video adaptor (not shown), or any other device necessary to render an image signal on a display device (not shown).

The transceiver 160 can include one or more transmitters and one or more receivers. The transceiver 160 can include a software defined radio (SDR).

The machine learning model builder 170 can include one or more computing resources, each arranged to run on the processor 110, or it can include one or more computing devices, each arranged to interact with the image pickup device 20 and/or communicating device 30 (shown in FIG. 1), or one or more of the components 110 to 160 and 180 to 190 in the predictive processor 100. The machine learning model builder 170 can include a supervised, unsupervised or both supervised and unsupervised machine learning systems. The machine learning system can include, for example, DNN, CAFFE, AIS, ANN, CNN, DCNN, R-CNN, YOLO, Mask-RCNN, DCED, RNN, NTM, DNC, SVM, DLNN, TNN, ReLu, pooling, inception, naïve Bayes, decision trees, LMT, NBTree classifier, case-based, linear regression, Q-learning, TD, deep adversarial networks, fuzzy logic, K-nearest neighbor, clustering, random forest, rough set, or any other machine learning platform capable of supervised or unsupervised learning.

The machine learning system 180 can include, or can interact with, the machine learning model builder 170. In various embodiments, the machine learning system 180 can include one or more computing resources, each arranged to run on the processor 110, or it can include one or more computing devices, each arranged to interact with any one or more of the components 110 to 170 and 190 in the predictive processor 100, or the image pickup device 10 and/or communicating device 30 (shown in FIG. 1).

The machine learning system 180 can include a supervised, unsupervised or both supervised and unsupervised machine learning systems. The machine learning system can include, for example, DNN, CAFFE, AIS, ANN, CNN, DCNN, R-CNN, YOLO, Mask-RCNN, DCED, RNN, NTM, DNC, SVM, DLNN, TNN, ReLu, pooling, inception, Naive Bayes, decision trees, LMT, NBTree classifier, case-based, linear regression, Q-learning, TD, deep adversarial networks, fuzzy logic, K-nearest neighbor, clustering, random forest, rough set, or any other machine learning platform capable of supervised or unsupervised learning.

In at least one embodiment, the machine learning system 180 includes the encoder 182, translator 184, and predictor 186. The machine learning system 180 can include one or more inputs and one or more outputs (input/output) 188. The encoder 182, translator 184, and predictor 186 can each be comprised of a computing resource or a computing device. In an embodiment, the machine learning system 180 can include a machine learning model consisting of the encoder 182, translator 184, predictor 186, and input/output 188.

The machine learning system 180 is arranged, once the machine learning model is trained and verified, to monitor and analyze one or more microscopic images of a target cell culture and predict a state of the cell culture at any time in the future. The machine learning system 180 can receive a sequence of microscopic images from the image pickup device 10 (shown in FIG. 1) in real-time (or near real-time) and monitor growth and changes in composition of cellular subpopulations through time and analyze the cell culture based on the live cell imaging to predict the absolute yields of various fates at a specified future time.

FIG. 6 shows a block diagram of a non-limiting embodiment of a machine learning model training process 200 that can be carried out by, for example, the machine learning model builder 170 (shown in FIG. 5) to build and train the machine learning (ML) model in the machine learning system 180. The machine learning model builder 170, through interaction with the communicating device 30 (shown in FIG. 1) or external input device (not shown), can create a training dataset to build and train the ML model. In an embodiment, the machine learning model builder 170 can include the MIA&I system discussed above.

Referring to FIG. 6, in an embodiment, the machine learning model builder 170 can receive a microscopic image frame from the image pickup device 10 (shown in FIG. 1) at Step 205. The microscopic image frame can be rendered on the display of the communicating device 30 as a still image frame and each feature in the image frame can be annotated at Step 210, including a label and description, for example, by an expert user at the communicating device 30. The annotation data can be received by the machine learning model builder 170 and associated with the corresponding image frame, at Step 210. The annotation data (or annotated image frame data) can be stored, for example, in the memory 120, at Step 215.

A determination can be made whether sufficient annotation data (or annotated image frame) has been created to building a training set sufficient to build and train the ML model, at Step 220. If sufficient annotation data exists (YES at Step 220), then the training set can be built, at Step 225, and stored, at Step 230, for use in training the ML model, otherwise (NO at Step 220) additional microscopic image frames can be received (Step 205) and annotated (Step 210). The training set can then be used by the machine learning system 180 to train and/or test the ML model.

In the embodiment depicted in FIG. 5, the machine learning model builder 170 can interact with the image pickup device 10 (shown in FIG. 1) and/or communication device 30 (shown in FIG. 1) via, for example, the network interface 130 or the IO interface 140.

In a non-limiting embodiment, the ML model(s) in the machine learning system 180 can be trained by, using the training set, to monitor, detect and analyze each feature in each microscopic image frame, including classifying each feature as a cell type (for example, a stem cell, a differentiated stem cell, and/or a progenitor of the differentiated stem cell), identify the target cell type (for example, a progenitor cell (including, but not limited to mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells), a differentiated stem cell that is comprised within the mesoderm, endoderm, and/or ectoderm, or a specific type of stem cell), and determine a yield of the target cell type with respect to the image frame.

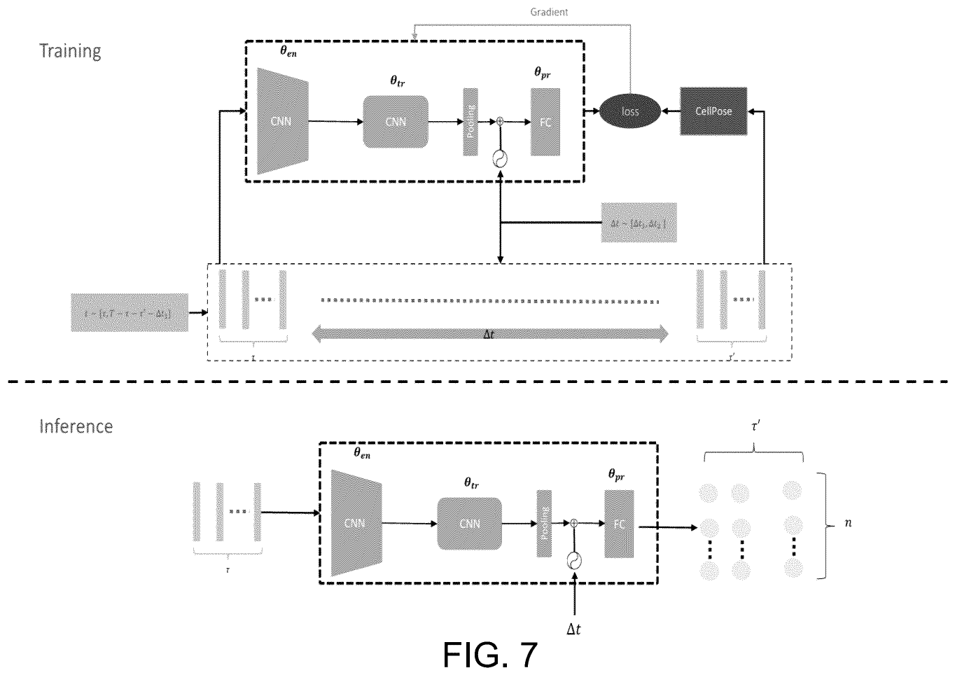

FIG. 7 shows a schematic detailing training and inference of the ML model based on the training set built by the training process 200, shown in FIG. 6.

FIG. 8 shows a forecasting process 300 for predicting a yield for different differentiations at any point in time.

Referring to FIGS. 1, 5 and 8 together, in an embodiment, the ML model in the machine learning system 180 can receive (for example, via a communication link, the network interface 130, and the input/output 188) and monitor a sequence of microscopic image frames from the image pickup device 10 (shown in FIG. 1), each image frame containing a high-resolution image of the target cell culture that was captured live, in real-time.

At Step 305, for each microscopic image frame in the sequence of microscopic image frames, the image frame is received, via the input/output 188, by the encoder 182, where it is encoded, at Step 310, to create a mathematical representation of each image frame in the sequence of microscopic image frames, including each feature in each image. In this regard, the encoder 182 extracts the spatial features from each microscopic image frame.

At Step 315, a sequence of image representations is input, over time, to the translator 184, where the image representations are aggregated and translated to create spatio-temporal information. In this regard, the translator 184 extracts temporal features to output (via the input/output 188) spatio-temporal information, at Step 320.

At Step 325, a determination is made whether a forecast query is received by the predictor 186, for example, via the input/output 188, from the communicating device 30 (shown in FIG. 1). If it is determined that a forecast query is received (YES at Step 325), then the query is parsed to retrieve and process the forecast time point (Step 330), otherwise (NO at Step 325) continues to monitor the target cell culture by repeating Steps 305 to 325.

At Step 335, the predictor 186 takes the spatio-temporal information and forecast time point as inputs and predicts yield of the target cell types at the time point. In an embodiment, the predictor 186 outputs a predicted yield and a prediction score, including the level of certainty the predicted yield will occur at the time point.

At Step 340, the predicted yield (for example, with prediction score) is output, via the input/output 188 and/or network interface 130 and/or IO interface 140, to an external device such as, for example, a display device (not shown) or the communicating device 30 (shown in FIG. 1).

In a nonlimiting implementation of the forecasting process 300 (shown in FIG. 8) by the predictive processor 100 (shown in FIG. 5), the encoder component θₑₙ is built on CNN. Referring to FIGS. 3-4 and 7, Ns convolution stacks of ConvNormReLU blocks (Conv2d+LayerNorm+LeakyReLU) are employed to extract spatial features, convoluting Cᵢ channels on (Hᵢ, Wᵢ). The hidden feature is zᵢ=LeakyReLu(LayerNorm(Conv2d(zᵢ₋₁), 1≤i≥Nₛ where the input zᵢ₋₁ and output zᵢ shapes are (τ, Cᵢ₋₁, Hᵢ₋₁, Wᵢ₋₁) and (τ, Cᵢ, Hᵢ, Wᵢ), respectively, with (C₀, H₀, W₀)=(1, H, W). All hidden channels can be set to fixed number Cᵢ=C_{Shid}. Thus, the encoder θₑₙ is the set of all learnable convolution weights across the Nₛ layers.

The translator component θₜᵣ is also built on CNN with Nₜ inception modules to learn temporal evolution convoluting τ×C_{Shid} channels on (H_{N}_{ₛ}, W_{N}_{ₛ}). The Inception module consists of a bottleneck Conv2d with 1×1 kernel followed by parallel GroupConv2d operators. The hidden feature is zᵢ=Inception(zᵢ₋₁), Nₛ<i≥Nₛ+Nₜ, where the input zᵢ₋₁ and output zᵢ shapes are (Cᵢ₋₁, H_{N}_{ₛ}, W_{N}_{ₛ}) and (Cᵢ, H_{N}_{ₛ}, W_{N}_{ₛ}), respectively, with C_{N}_{ₛ}=τ×C_{Shid}, Cᵢ=C_{Thid}, for i>Nₛ and C_{N}_{ₛ}+Nₜ=τ′×C_{Shid}. Thus, the translator θₜᵣ is the set of all learnable convolution weights across the Nₜ layers.

The predictor component θₚᵣ takes the extracted spatio-temporal features in tensor shape (τ′, C_{Shid}, H_{N}_{ₛ}, W_{N}_{ₛ}), it applies 3d adaptive pooling along H_{N}_{ₛ}, W_{N}_{ₛ} resulting in (τ′, C_{Shid}, H′, W′), flatten along spatial resolutions into (τ′, C_{Shid}, H′×W′), then applies positional temporal embedding using Δts to queried future frames. The resulting embedding are then fed to a fully connected neural network with Nₚ layers each with hₚ hidden dimensions, it outputs an embedding of shape (τ′, hₚ) which is fed to a final linear layer outputting yield prediction vector (τ′, n) that is post-processed into integer vectors [symbol] ^{τ′×n}

In various embodiments, the CNN can include a plurality of convolutional layers (for example, CONV 1 and CONV 2), a plurality of rectified linear unit layers (ReLU), a plurality of pooling layers (for example, POOL 1, POOL 2), and a fully connected layer. Each ReLU layer can be located between a convolution layer and a pooling layer. The fully connected layer can include a plurality of hidden layers and an output layer. Data can be flattened before it is transferred from the last pooling layer (for example, POOL 2) to the first hidden layer in the fully connected layer.

It is noted that the fully connected layer can have at least three outputs, including, for example, (i) a feature class, (ii) an x-coordinate and (iii) a y-coordinate, or (i) a feature class, (ii) an x-coordinate (or bearing), (iii) a y-coordinate (distance) and (iv) a z-coordinate (elevation). In this regard, the ML model can be used to estimate the distance (y), bearing (x), and the elevation (z) of a feature in the microscopic image frame.

In an embodiment, the CNN includes an input layer and four convolution layers (instead of the two CONV 1 and CONV 2) followed by a regression layer. The input layer can supply a greyscale image comprising 26×45 pixels to the first convolution layer having eight filters with a 3×3×1 pixel grid, which can be arranged to filter the image data with batch normalization, ReLU activation and average pooling before supplying the result to the second convolution layer. The second convolution can have sixteen filters with a 3×3×8 pixel grid, which can be arranged to filter the output from the first convolution layer with batch normalization, ReLU activation and average pooling before supplying the result to the third and fourth convolution layers, each having thirty-two filters and arranged to carry out normalization, ReLU activation and average pooling, except that the third convolution layer uses 3×3×16 pixel grids and the fourth convolution layer uses 3×3×32 pixel grids. The output from the fourth convolution layer can be input to the fully connected or regression layer, which can include at least three (3) outputs—for example, (i) a feature class, (ii) an x-coordinate (or bearing), (iii) a y-coordinate (distance) and (iv) a z-coordinate (elevation).

The filter matrix in the first, second, third and fourth convolution layers can be set to, for example, 3×3×1 pixels, 3×3×8 pixels, 3×3×16 pixels and 3×3×32 pixels, respectively. In each convolution layer, the filter matrix can be successively slid and applied across each pixel matrix to compute dot products and locate features. After applying the four convolution layers to the image data, the resultant data arrays output from the fourth convolution layer can be input to the fully connected or regression layer. The fully connected layer can auto-encode the feature data and classify the image data to provide at least three outputs, as discussed above.

Using the CNN, the ML model can monitor, classify and identify each feature and its location in the image frame, including the target cell and surroundings in the image. In this regard, each image frame can be divided into discrete cells, bounding boxes determined for each cell, and objects predicted in each bounding box. Once the ML model is trained, the image frames received from the image pickup device 10 (shown in FIG. 1) can be analyzed in real-time to detect and identify each feature and cell type in the image, including the target cell and surroundings, as well as their respective locations.

In an embodiment, the machine learning system 180 can include a Faster R-CNN or Mask-RCNN, which can include a feature detection methodology that can mark out each feature in the image frame, including each distinct feature of interest appearing in the image. The machine learning system 180 can label each pixel with feature and location information.

In various embodiments, the output (for example, at Step 340 in FIG. 8) can be applied to the ML model to tune the parametric values of the ML model.

In an embodiment, the ML model includes the following model hyper-parameters: for the encoder, Nₛ=4, C_{Shid}=8, and number of convolution groups is 8; for the translator, Nₜ=4, C_{Thid}=8; and, for the predictor, Nₚ=2, hₚ=512. The pooling resolution is H′=12, W′=12. The ML model uses 60 input frames and forecast yield of 2 output frames, τ=60, τ′=2.

Referring to FIG. 7, the ML model can be trained on three days differentiation data and validation can be performed on separate wells. The ML model can be run for 2000 iterations using Adamw optimizer with learning rate set at 0.001, batch size set to 8, L2 loss computed against randomly queried future frames within temporal interval between 10 and 90 delta frames. That is, the queried Δt during training can be constrained between 10*5 and 90*5 minutes. For this data, it can be assumed that at day 3 all cells are differentiated into the target fate, without using then the gene marker to get fate ground truth.

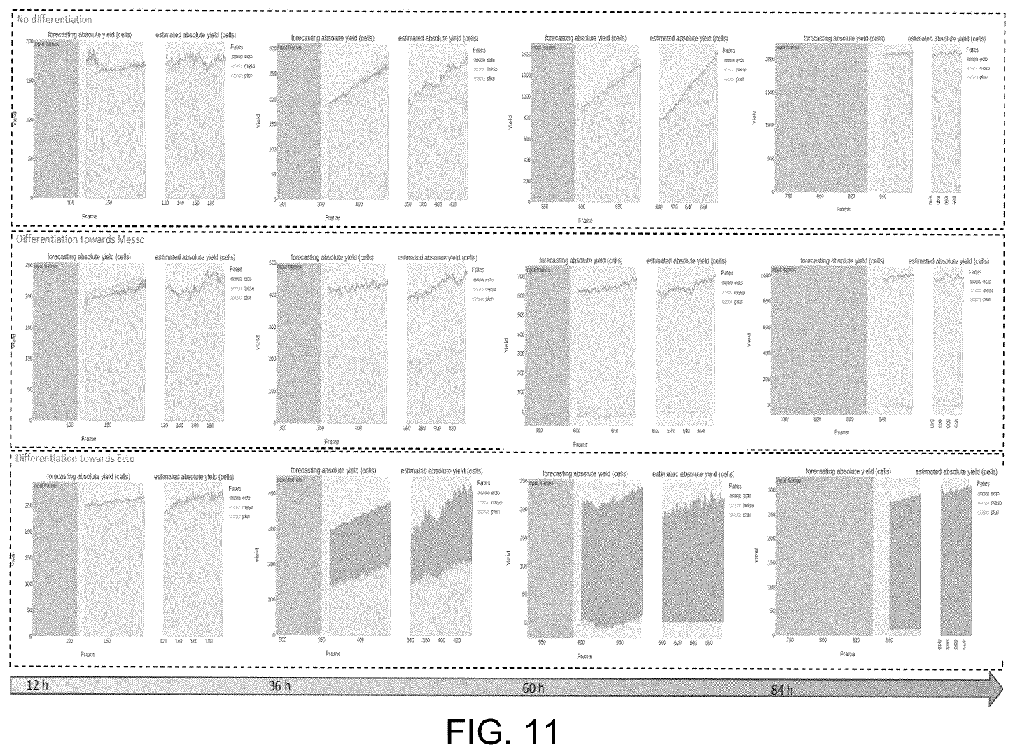

Referring to FIG. 11, a plurality of snapshots of the predicted yield are shown for two different differentiations: to ecto and to meso as well no differentiation. The snapshots are taken at 12 h, 36 h, 60 h, and 84 h. Each snapshot illustrates the forecasted absolute yields for every fate (ecto, meso or pluri) and the estimated absolute yield computed using the nuclear channel frames, (it is assumed that at day 3 all cells have been differentiated to the target fate). The forecast is performed using sliding input windows of size τ=8 forecasting yields in sliding output window of size τ′=2, note that for an input window multiple querying times are applied ranging from Δt∈[10*5, (90−2)*5].

The terms “a,” “an,” and “the,” as used in this disclosure, means “one or more,” unless expressly specified otherwise.

The term “absolute yield” as used in this disclosure, means the number of cells of a certain cell type or fate that arise during the stem cell differentiation process. By way of an example a stem cell can be differentiated into three germ layers, the mesoderm, the endoderm, and/or the ectoderm. Absolute yield can refer to the amount of endoderm cells or any progenitor cell thereof produced at any point during the stem cell differentiation process. “Absolute yield” can, for example, also refer to the growth of the target cell type during the stem cell differentiation process, i.e., the division rate of each target cell type. “Absolute yield” can, for example, also refer to the specific composition of the subpopulations of cells in the cell culture, i.e., the composition of the populations of stem cells, differentiated stem cells, and any progenitor cells produced during the differentiation process that have not fully differentiated to the final target cell type.

The term “backbone,” as used in this disclosure, means a transmission medium that interconnects one or more computing devices or communicating devices to provide a path that conveys data signals and instruction signals between the one or more computing devices or communicating devices. The backbone can include a bus or a network. The backbone can include an ethernet TCP/IP. The backbone can include a distributed backbone, a collapsed backbone, a parallel backbone or a serial backbone.

The term “bus,” as used in this disclosure, means any of several types of bus structures that can further interconnect to a memory bus (with or without a memory controller), a peripheral bus, or a local bus using any of a variety of commercially available bus architectures. The term “bus” can include a backbone.

The terms “communicating device” and “communication device,” as used in this disclosure, mean any hardware, firmware, or software that can transmit or receive data packets, instruction signals, data signals or radio frequency signals over a communication link. The device can include a computer or a server. The device can be portable or stationary.

The term “communication link,” as used in this disclosure, means a wired or wireless medium that conveys data or information between at least two points. The wired or wireless medium can include, for example, a metallic conductor link, a radio frequency (RF) communication link, an Infrared (IR) communication link, or an optical communication link. The RF communication link can include, for example, WiFi, WiMAX, IEEE 802.11, DECT, 0G, 1G, 2G, 3G, 4G, or 5G cellular standards, or Bluetooth. A communication link can include, for example, an RS-232, RS-422, RS-485, or any other suitable serial interface.

The terms “computer,” “computing device,” or “processor,” as used in this disclosure, means any machine, device, circuit, component, or module, or any system of machines, devices, circuits, components, or modules that are capable of manipulating data according to one or more instructions. The terms “computer,” “computing device” or “processor” can include, for example, without limitation, a communicating device, a computer resource, a processor, a microprocessor (μC), a central processing unit (CPU), a graphic processing unit (GPU), an application specific integrated circuit (ASIC), a general purpose computer, a super computer, a personal computer, a laptop computer, a palmtop computer, a notebook computer, a desktop computer, a workstation computer, a server, a server farm, a computer cloud, or an array or system of processors, μCs, CPUs, GPUs, ASICs, general purpose computers, super computers, personal computers, laptop computers, palmtop computers, notebook computers, desktop computers, workstation computers, or servers.

The terms “computing resource” or “computer resource,” as used in this disclosure, means software, a software application, a web application, a web page, a computer application, a computer program, computer code, machine executable instructions, firmware, or a process that can be arranged to execute on a computing device as one or more processes.

The term “computer-readable medium,” as used in this disclosure, means any non-transitory storage medium that participates in providing data (for example, instructions) that can be read by a computer. Such a medium can take many forms, including non-volatile media and volatile media. Non-volatile media can include, for example, optical or magnetic disks and other persistent memory. Volatile media can include dynamic random-access memory (DRAM). Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, a carrier wave as described hereinafter, or any other medium from which a computer can read. The computer-readable medium can include a “cloud,” which can include a distribution of files across multiple (e.g., thousands of) memory caches on multiple (e.g., thousands of) computers.

Various forms of computer readable media can be involved in carrying sequences of instructions to a computer. For example, sequences of instruction (i) can be delivered from a RAM to a processor, (ii) can be carried over a wireless transmission medium, or (iii) can be formatted according to numerous formats, standards or protocols, including, for example, WiFi, WiMAX, IEEE 802.11, DECT, 0G, 1G, 2G, 3G, 4G, or 5G cellular standards, or Bluetooth.

The term “current state of a cell culture,” as used herein, refers to the state of the cell culture at the time a request for a yield of a target cell type is received by the one or more processors. The current state of a cell culture can, for example, refer to the instant state of the cell culture at the time the one or more images of the cell culture are captured by an image capture device. The information captured from the one or more images can be combined with additional measurements selected from, but not limited to, the pH of the cell culture, the temperature of the cell culture, the dissolved oxygen level of the cell culture, the glucose/lactate level for the current and/or past time points of the cell culture. Combining the additional measurements with the one or more images can aid in describing the current state of the cell culture.

The term “database,” as used in this disclosure, means any combination of software or hardware, including at least one computing resource or at least one computer. The database can include a structured collection of records or data organized according to a database model, such as, for example, but not limited to at least one of a relational model, a hierarchical model, or a network model. The database can include a database management system application (DBMS). The at least one application may include, but is not limited to, a computing resource such as, for example, an application program that can accept connections to service requests from communicating devices by sending back responses to the devices. The database can be configured to run the at least one computing resource, often under heavy workloads, unattended, for extended periods of time with minimal or no human direction.

The term “future state of a cell culture,” as used herein, refers to the state of the cell culture at any time point in the future. By way of an example, the future state of a cell culture can be the state of the cell culture at the end of the experiment (i.e., at the end of a stem cell differentiation process). Alternatively, the future state of a cell culture can be at least 1 day, at least 2 days, at least 3 days, at least 4 days, at least 5 days, at least 6 days, at least 7 days, at least 8 days, at least 9 days, or at least 10 days from the current day that the request for a yield of a target cell type is provided to the one or more processors. Alternatively, the future state of a cell culture can be at least 1 hour, at least 2 hours, at least 3 hours, at least 4 hours, at least 5 hours, at least 6 hours, at least 7 hours, at least 8 hours, at least 9 hours, or at least 10 hours from the current hour that the request for a yield of a target cell type is provided to the one or more processors. The future state of the cell culture can refer to the absolute yield of the cell culture, i.e., the number of cells of a certain cell type or fate that arise during the stem cell differentiation process; the growth of the target cell type during the stem cell differentiation process; and/or the specific composition of the subpopulations of cells in the stem cell culture during the differentiation process or at the conclusion of the differentiation process.

The terms “including,” “comprising” and their variations, as used in this disclosure, mean “including, but not limited to,” unless expressly specified otherwise.

The term “network,” as used in this disclosure means, but is not limited to, for example, at least one of a personal area network (PAN), a local area network (LAN), a wireless local area network (WLAN), a campus area network (CAN), a metropolitan area network (MAN), a wide area network (WAN), a metropolitan area network (MAN), a wide area network (WAN), a global area network (GAN), a broadband area network (BAN), a cellular network, a storage-area network (SAN), a system-area network, a passive optical local area network (POLAN), an enterprise private network (EPN), a virtual private network (VPN), the Internet, or the like, or any combination of the foregoing, any of which can be configured to communicate data via a wireless and/or a wired communication medium. These networks can run a variety of protocols, including, but not limited to, for example, Ethernet, IP, IPX, TCP, UDP, SPX, IP, IRC, HTTP, FTP, Telnet, SMTP, DNS, ARP, ICMP.

The term “server,” as used in this disclosure, means any combination of software or hardware, including at least one computing resource or at least one computer to perform services for connected communicating devices as part of a client-server architecture. The at least one server application can include, but is not limited to, a computing resource such as, for example, an application program that can accept connections to service requests from communicating devices by sending back responses to the devices. The server can be configured to run the at least one computing resource, often under heavy workloads, unattended, for extended periods of time with minimal or no human direction. The server can include a plurality of computers configured, with the at least one computing resource being divided among the computers depending upon the workload. For example, under light loading, the at least one computing resource can run on a single computer. However, under heavy loading, multiple computers can be required to run the at least one computing resource. The server, or any if its computers, can also be used as a workstation.

The terms “send,” “sent,” “transmission,” or “transmit,” as used in this disclosure, means the conveyance of data, data packets, computer instructions, or any other digital or analog information via electricity, acoustic waves, light waves or other electromagnetic emissions, such as those generated with communications in the radio frequency (RF) or infrared (IR) spectra. Transmission media for such transmissions can include coaxial cables, copper wire and fiber optics, including the wires that comprise a system bus coupled to the processor.

Devices that are in communication with each other need not be in continuous communication with each other unless expressly specified otherwise. In addition, devices that are in communication with each other may communicate directly or indirectly through one or more intermediaries.

Although process steps, method steps, or algorithms may be described in a sequential or a parallel order, such processes, methods and algorithms may be configured to work in alternate orders. In other words, any sequence or order of steps that may be described in a sequential order does not necessarily indicate a requirement that the steps be performed in that order; some steps may be performed simultaneously. Similarly, if a sequence or order of steps is described in a parallel (or simultaneous) order, such steps can be performed in a sequential order. The steps of the processes, methods or algorithms described in this specification may be performed in any order practical.

When a single device or article is described, it will be readily apparent that more than one device or article may be used in place of a single device or article. Similarly, where more than one device or article is described, it will be readily apparent that a single device or article may be used in place of the more than one device or article. The functionality or the features of a device may be alternatively embodied by one or more other devices which are not explicitly described as having such functionality or features.

The subject matter described above is provided by way of illustration only and should not be construed as limiting. Various modifications and changes can be made to the subject matter described herein without following the example embodiments and applications illustrated and described, and without departing from the true spirit and scope of the invention encompassed by the present disclosure, which is defined by the set of recitations in the following claims and by structures and functions or steps which are equivalent to these recitations.

### Embodiments

The invention provides also the following non-limiting embodiments.

Embodiment 1 is a method of predicting a future state of a cell culture based on a current state of the cell culture, the method comprising:
(a) receiving, by one or more processors, a request for a yield of a target cell type at a specific time in the future;
(b) receiving, by the one or more processors, one or more images of a cell culture of the target cell type, wherein each of the one or more images include discrete image frames of the cell culture captured in real-time by an image pickup device;
(c) providing, by the one or more processors, the one or more images of the cell culture to a machine learning system;
(d) generating, by the machine learning system, a mathematical representation of each of the one or more images of the cell culture;
(e) aggregating, by the machine learning system, temporal information based on the mathematical representation of each of the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device, wherein the communication device is configured to render the target cell type at the specific time on an output device.

Embodiment 2 is the method of embodiment 1, wherein the cell culture comprises a stem cell culture.

Embodiment 3 is the method of embodiment 2, wherein the stem culture comprises an embryonic stem cell culture, an adult stem cell culture, an induced pluripotent stem cell culture, or a trophoblast stem cell culture.

Embodiment 4 is the method of embodiment 2 or 3, wherein the stem cell culture comprises a mesenchymal stem cell culture, a hematopoietic stem cell culture, a neural stem cell culture, an epithelial stem cell culture, or a cord blood stem cell culture.

Embodiment 5 is the method of any one of embodiments 2 to 4, wherein the stem cell culture is undergoing a differentiation process.

Embodiment 6 is the method of embodiment 5, wherein the stem cell culture comprises progenitor cells.

Embodiment 7 is the method of embodiment 6, wherein the progenitor cells are selected from mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells.

Embodiment 8 is the method of any one of embodiments 5 to 7, wherein the differentiation process results in the stem cell culture differentiating to a mesoderm, endoderm, and/or ectoderm.

Embodiment 9 is the method of embodiment 8, wherein the mesoderm comprises a skeletal muscle cell, a kidney cell, a red blood cell, or a smooth muscle cell.

Embodiment 10 is the method of embodiment 8, wherein the endoderm comprises a lung cell, a thyroid cell, or a pancreatic cell.

Embodiment 11 is the method of embodiment 8, wherein the ectoderm comprises a skin cell, a neuron cell, or a pigment cell.

Embodiment 12 is the method of any one of embodiments 5 to 11, wherein predicting the future state of the cell culture comprises predicting the growth of the cells, predicting the total amount of cells, and/or predicting the composition of subpopulations of cells in the cell culture.

Embodiment 13 is the method of any one of embodiments 1 to 12, wherein the predicting the future state of the cell culture comprises predicting the state of the cell culture at the next time point an image is captured, at the next two time points an image is capture, and/or at any time point an image is captured.

Embodiment 14 is the method of any one of embodiments 1 to 13, wherein the method further comprises
(b) receiving, by one or more processors, an input of one or more protocol actions for the cell culture;
(c) providing, by the one or more processors, the input of the one or more protocol actions for the cell culture to a machine learning system;
(d) generating, by the machine learning system, a mathematical representation of the one or more protocol actions in combination with the one or more images of the cell culture; (e) aggregating, by the machine learning system, temporal information based on the mathematical representation of the one or more protocol actions in combination with the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device, wherein the communication device is configured to render the target cell type at the specific time on an output device.

Embodiment 15 is a computing system for predicting a future state of a cell culture based on a current state of the cell culture, the system comprising:
(a) a receiver configured to receive from a communication device a request for a yield of a target cell type at a specific time in the future;
(b) one or more processors configured to receive one or more images of a cell culture of the target cell type, wherein each of the one or more images include discrete image frames of the cell culture captured in real-time by an image pickup device;
(c) a machine learning system configured to receive the one or more images of the cell culture to a machine learning system, generate a mathematical representation of each of the one or more images of the cell culture,
aggregate temporal information based on the mathematical representation of each of the one or more images of the cell culture to generate spatio-temporal information, predict the yield of the target cell type at the specific time in the future based on the spatio-temporal information; and
(d) a transmitter configured to send the yield of the target cell type at the specific time to a communication device.

Embodiment 16 is the system in embodiment 15, wherein the machine learning system comprises:
an encoder configured to generate the mathematical representation of each of the one or more images of the cell culture;
a translator configured to take the mathematical representation of each of the one or more images of the cell culture and create spatio-temporal information for the cell culture; and
a predictor configured to take the spatio-temporal information and predict the yield of the target cell type at the specific time in the future based on the spatio-temporal information.

Embodiment 17 is the system in embodiment 15 or 16, wherein the machine learning system comprises an artificial neural network.

Embodiment 18 is the system in any of embodiments 15 to 17, wherein the machine learning system comprises a convolutional neural network (CNN).

Embodiment 19 is the system in any of embodiments 15 to 17, wherein the machine learning system comprises a transformer neural network (TNN).

Embodiment 20 is a non-transitory computer readable storage medium storing one or more programs, the one or more programs comprising instructions, which, when executed by one or more processors, perform:
(a) receiving, by the one or more processors, a request for a yield of a target cell type at a specific time in the future;
(b) receiving, by the one or more processors, one or more images of a cell culture of the target cell type, wherein each of the one or more images include discrete image frames of the cell culture captured in real-time by an image pickup device;
(c) providing, by the one or more processors, the one or more images of the cell culture to a machine learning system;
(d) generating, by the machine learning system, a mathematical representation of each of the one or more images of the cell culture;
(e) aggregating, by the machine learning system, temporal information based on the mathematical representation of each of the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
wherein the communication device is configured to render the target cell type at the specific time on an output device.

Embodiment 21 is the non-transitory computer readable storage medium in embodiment 20, wherein the cell culture comprises a stem cell culture.

Embodiment 22 is the non-transitory computer readable storage medium in embodiment 21, wherein the stem culture comprises an embryonic stem cell culture, an adult stem cell culture, an induced pluripotent stem cell culture, or a trophoblast stem cell culture.

Embodiment 23 is the non-transitory computer readable storage medium in embodiments 20 or 21, wherein the stem cell culture comprises a mesenchymal stem cell culture, a hematopoietic stem cell culture, a neural stem cell culture, an epithelial stem cell culture, or a cord blood stem cell culture.

Embodiment 24 is the non-transitory computer readable storage medium in any one of embodiments 20 to 23, wherein the stem cell culture is undergoing a differentiation process.

Embodiment 25 is the non-transitory computer readable storage medium in embodiment 24, wherein the stem cell culture comprises progenitor cells.

Embodiment 26 is the non-transitory computer readable storage medium in embodiment 25, wherein the progenitor cells are selected from mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells.

Embodiment 27 is the non-transitory computer readable storage medium in any one of embodiments 24 to 26, wherein the differentiation process results in the stem cell culture differentiating to a mesoderm, endoderm, and/or ectoderm.

Embodiment 28 is the non-transitory computer readable storage medium in embodiment 27, wherein the mesoderm comprises a skeletal muscle cell, a kidney cell, a red blood cell, or a smooth muscle cell.

Embodiment 29 is the non-transitory computer readable storage medium in embodiment 27, wherein the endoderm comprises a lung cell, a thyroid cell, or a pancreatic cell.

Embodiment 30 is the non-transitory computer readable storage medium in embodiment 27, wherein the ectoderm comprises a skin cell, a neuron cell, or a pigment cell.

Embodiment 31 is the non-transitory computer readable storage medium in any one of embodiments 24 to 30, wherein predicting the future state of the cell culture comprises predicting the growth of the cells, predicting the total amount of cells, and/or predicting the composition of subpopulations of cells in the cell culture.

Embodiment 32 is the non-transitory computer readable storage medium in any one of embodiments 20 to 31, wherein the predicting the future state of the cell culture comprises predicting the state of the cell culture at the next time point an image is captured, at the next two time points an image is capture, and/or at any time point an image is captured.

Embodiment 33 is the non-transitory computer readable storage medium in any one of embodiments 20 to 32, wherein the one or more processors further performs:
(b) receiving, by one or more processors, an input of one or more protocol actions for the cell culture;
(c) providing, by the one or more processors, the input of the one or more protocol actions for the cell culture to a machine learning system;
(d) generating, by the machine learning system, a mathematical representation of the one or more protocol actions in combination with the one or more images of the cell culture; (e) aggregating, by the machine learning system, temporal information based on the mathematical representation of the one or more protocol actions in combination with the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
   wherein the communication device is configured to render the target cell type at the specific time on an output device.

### EXAMPLES

### Example 1: Machine Learning Model Used to Predict Fate of Cell Culture System

Stem cell culturing: Huma Pluripotent cells were maintained under essential E8 (A1517001, Thermo Fisher; Waltham, MA) medium on Vitronectin (AF-140-09, Peprotech; Thermo Fisher)-coated plates. The medium was changed daily.

Stem cell differentiation: To differentiate cells into the three germ layers, human pluripotent cells (hPCs) were seeded, as a monolayer culture, into a 96-well imaging plate twenty-four hours before being exposed to trilineage differentiation media (STEMdiff™ Trilineage Differentiation Kit, StemCell Technologies (Vancouver, Canada) or PSC neural induction medium [A1647801, Thermo Fisher], cardiomyocyte differentiation kit [A2921201, Thermo Fisher] and PSC definitive endodermal induction kit [A3062601, Thermo Fisher]) according to the manufacturer's instruction. For the spontaneous differentiation, cells were switched into DMEM/F12, (1×NEAA, 1×GlutaMAX, 1×P/S, 1% B-mercaptoethanol) supplemented with 10% FBS.

Cells were cultured under these conditions for three and six days and the media refreshed every day.

Ground Truth Generation: To prove correct induced or spontaneous differentiation, after three and six days of differentiation, cells were stained for the expression of Pluripotency (Oct4) and differentiation (Ectoderm, Sox1; Mesoderm, Brachyury; Endoderm, Sox17) markers. Briefly, cells were fixed in 4% PFA for 10 minutes, subsequently blocked in PBS 0.01% Triton and 3% BSA for 1 hour at room temperature and incubated with specific primary antibodies (1:200) overnight. The day after, primary antibodies were washed out, and the cells were incubated with fluorescence-conjugated secondary antibodies (1:1000) for 1 hour at room temperature. DAPI solution was used to detect nuclei.

Ground truth for fate forecasting was inferred by using Cellpose (Stringer et al., Nat. Methods 18(1):100-106 (2021)) to segment individual cell nuclei on the DAPI channel. The fate of each individual cell was then assigned based on the assumption that all cells of differentiation towards target fate x are of target fate x on the day 3 experiments. That is, it was assumed that all cells successfully differentiated into the target fate. Lastly, the number of cells of each fate was counted.

Image acquisition: Cells were imaged for the entire duration of the differentiation experiment from fluorescent and/or phase contrast channels (according to experimental needs). Acquisition time is one frame every 5 minutes.

FateCast Model: The following model hyper-parameters were used: (1) for the encoder, Nₛ=4, C_{Shid}=8, and number of convolution groups to 8 was set; (2) for the translator, Nₜ=4, C_{Thid}=8 was set; (3) for the predictor, Nₚ=2, hₚ=512 was set. The pooling resolution is H′=12, W′=12.60 input frames were used, and a forecast yield of 2 output frames, τ=60, τ′=2 was produced.

Training: Fatecast was trained on three days differentiation data and validation was performed on separate wells. The model was run for 2000 iterations using Adamw optimizer with a learning rate set at 0.001, a batch size was set to 8, L2 loss was computed against randomly queried future frames within temporal interval between 10 and 90 delta frames. That is, the queried Δt during training is constrained between 10 and 90 timesteps, where one image is taken every five (5) minutes, translating to 50 to 450 minutes. [For this data, it was assumed that at day 3, all cells were differentiated into the target fate, and a gene marker was not used to get fate ground truth]

### RESULTS

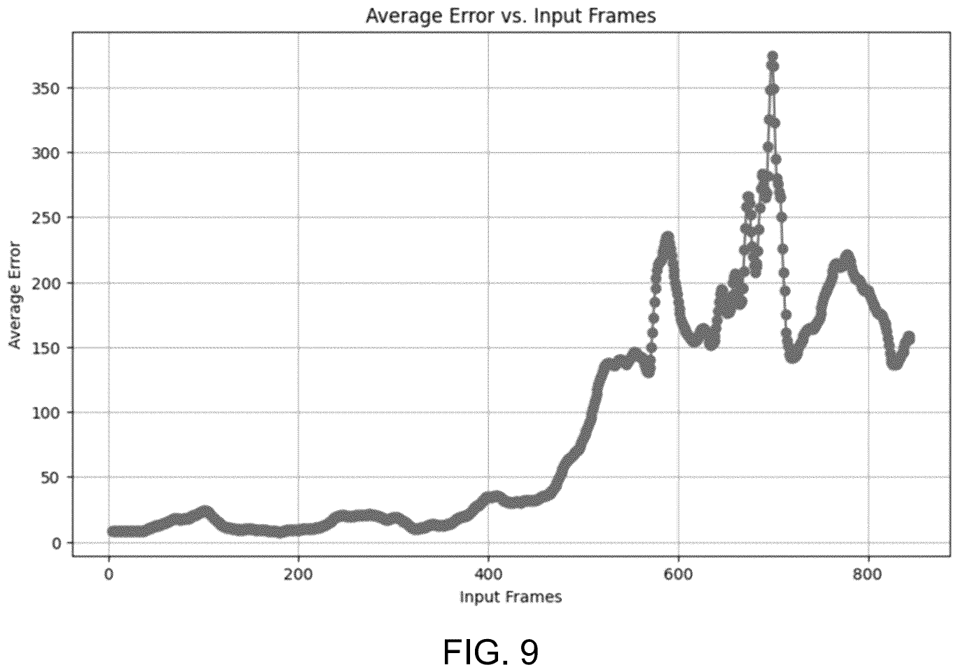

In FIG. 9, the average error is plotted with respect to the input frames. The average error was with respect to all queries within the allowed querying interval between 10 and 90 delta frames and with respect to the cell type. It was noticeable that the error peaks around the frames of day 2 when differentiation is happening. The average input frame error: 85 cells, which is compared to the number of cells per image, where the number is typically on average 1000 cells per image.

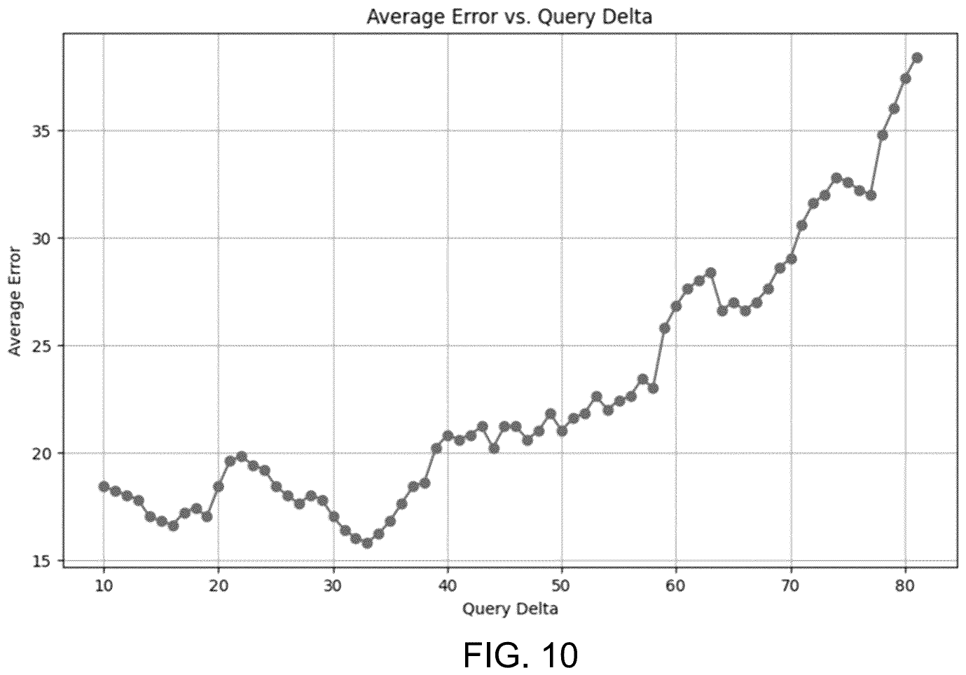

In FIG. 10, the average error is plotted with respect to input queries. The average error was with respect to all input frames and with respect to the cell type. The error increases with respect to the querying delta. The average query error: 23 cells, which is compared to the number of cells per image, where the number is typically on average 1000 cells per image.

FIG. 11 shows snapshots of the predicted yield for two different differentiations: to ecto and to meso as well as no differentiation. The snapshots were taken at 12 hours, 36 hours, 60 hours, and 84 hours. Each snapshot illustrated the forecasted absolute yields for every fate (ecto, meso or pluri) and the estimated absolute yield was computed using the nuclear channel frames, (it was assumed that at day 3, all cells were differentiated to the target fate). The forecast was performed using sliding input windows of size τ=8 forecasting yields in sliding output window of size τ′=2, note that for an input window multiple querying times were applied ranging from Δt∈[10*5, (90−2)*5].

What is claimed is:

1. A method of predicting a future state of a cell culture based on a current state of the cell culture, the method comprising:
(a) receiving, by one or more processors, a request for a yield of a target cell type at a specific time in the future;
(b) receiving, by the one or more processors, one or more images of a cell culture of the target cell type, wherein each of the one or more images include discrete image frames of the cell culture captured in real-time by an image pickup device;
(c) providing, by the one or more processors, the one or more images of the cell culture to a machine learning system;
(d) generating, by the machine learning system, a mathematical representation of each of the one or more images of the cell culture;
(e) aggregating, by the machine learning system, temporal information based on the mathematical representation of each of the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
wherein the communication device is configured to render the target cell type at the specific time on an output device.

2. The method of claim 1, wherein the cell culture comprises a stem cell culture.

3. The method of claim 2, wherein the stem culture comprises an embryonic stem cell culture, an adult stem cell culture, an induced pluripotent stem cell culture, or a trophoblast stem cell culture.

4. The method of claim 2, wherein the stem cell culture comprises a mesenchymal stem cell culture, a hematopoietic stem cell culture, a neural stem cell culture, an epithelial stem cell culture, or a cord blood stem cell culture.

5. The method of claim 2, wherein the stem cell culture is undergoing a differentiation process.

6. The method of claim 2, wherein the stem cell culture comprises progenitor cells.

7. The method of claim 6, wherein the progenitor cells are selected from mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells.

8. The method of claim 5, wherein the differentiation process results in the stem cell culture differentiating to a mesoderm, endoderm, and/or ectoderm.

9. The method of claim 8, wherein the mesoderm comprises a skeletal muscle cell, a kidney cell, a red blood cell, or a smooth muscle cell.

10. The method of claim 8, wherein the endoderm comprises a lung cell, a thyroid cell, or a pancreatic cell.

11. The method of claim 8, wherein the ectoderm comprises a skin cell, a neuron cell, or a pigment cell.

12. The method of claim 5, wherein predicting the future state of the cell culture comprises predicting the growth of the cells, predicting the total amount of cells, and/or predicting the composition of subpopulations of cells in the cell culture.

13. The method of claim 1, wherein the predicting the future state of the cell culture comprises predicting the state of the cell culture at the next time point an image is captured, at the next two time points an image is capture, and/or at any time point an image is captured.

14. The method of claim 1, wherein the method further comprises
(b) receiving, by one or more processors, an input of one or more protocol actions for the cell culture;
(c) providing, by the one or more processors, the input of the one or more protocol actions for the cell culture to a machine learning system;
(d) generating, by the machine learning system, a mathematical representation of the one or more protocol actions in combination with the one or more images of the cell culture;
(e) aggregating, by the machine learning system, temporal information based on the mathematical representation of the one or more protocol actions in combination with the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
wherein the communication device is configured to render the target cell type at the specific time on an output device.

15. A computing system for predicting a future state of a cell culture based on a current state of the cell culture, the system comprising:
(a) a receiver configured to receive from a communication device a request for a yield of a target cell type at a specific time in the future;
(b) one or more processors configured to receive one or more images of a cell culture of the target cell type, wherein each of the one or more images include discrete image frames of the cell culture captured in real-time by an image pickup device;
(c) a machine learning system configured to
receive the one or more images of the cell culture to a machine learning system,
generate a mathematical representation of each of the one or more images of the cell culture,
aggregate temporal information based on the mathematical representation of each of the one or more images of the cell culture to generate spatio-temporal information,
predict the yield of the target cell type at the specific time in the future based on the spatio-temporal information; and
(d) a transmitter configured to send the yield of the target cell type at the specific time to a communication device.

16. The system in claim 15, wherein the machine learning system comprises:
an encoder configured to generate the mathematical representation of each of the one or more images of the cell culture;
a translator configured to take the mathematical representation of each of the one or more images of the cell culture and create spatio-temporal information for the cell culture; and
a predictor configured to take the spatio-temporal information and predict the yield of the target cell type at the specific time in the future based on the spatio-temporal information.

17. The system in claim 15, wherein the machine learning system comprises an artificial neural network.

18. The system in claim 15, wherein the machine learning system comprises a convolutional neural network (CNN).

19. The system in claim 15, wherein the machine learning system comprises a transformer neural network (TNN).

20. A non-transitory computer readable storage medium storing one or more programs, the one or more programs comprising instructions, which, when executed by one or more processors, perform:
(a) receiving, by the one or more processors, a request for a yield of a target cell type at a specific time in the future;
(b) receiving, by the one or more processors, one or more images of a cell culture of the target cell type, wherein each of the one or more images include discrete image frames of the cell culture captured in real-time by an image pickup device;
(c) providing, by the one or more processors, the one or more images of the cell culture to a machine learning system;
(d) generating, by the machine learning system, a mathematical representation of each of the one or more images of the cell culture;
(e) aggregating, by the machine learning system, temporal information based on the mathematical representation of each of the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
wherein the communication device is configured to render the target cell type at the specific time on an output device.

21. The non-transitory computer readable storage medium in claim 20, wherein the cell culture comprises a stem cell culture.

22. The non-transitory computer readable storage medium in claim 21, wherein the stem culture comprises an embryonic stem cell culture, an adult stem cell culture, an induced pluripotent stem cell culture, or a trophoblast stem cell culture.

23. The non-transitory computer readable storage medium in claim 20, wherein the stem cell culture comprises a mesenchymal stem cell culture, a hematopoietic stem cell culture, a neural stem cell culture, an epithelial stem cell culture, or a cord blood stem cell culture.

24. The non-transitory computer readable storage medium in claim 20, wherein the stem cell culture is undergoing a differentiation process.

25. The non-transitory computer readable storage medium in claim 24, wherein the stem cell culture comprises progenitor cells.

26. The non-transitory computer readable storage medium in claim 25, wherein the progenitor cells are selected from mesodermal progenitor cells, endodermal progenitor cells, ectodermal progenitor cells, neural progenitor cells, cardiac progenitor cells, hematopoietic progenitor cells, mesenchymal stem cells, and/or pancreatic progenitor cells.

27. The non-transitory computer readable storage medium in claim 24, wherein the differentiation process results in the stem cell culture differentiating to a mesoderm, endoderm, and/or ectoderm.

28. The non-transitory computer readable storage medium in claim 27, wherein the mesoderm comprises a skeletal muscle cell, a kidney cell, a red blood cell, or a smooth muscle cell.

29. The non-transitory computer readable storage medium in claim 27, wherein the endoderm comprises a lung cell, a thyroid cell, or a pancreatic cell.

30. The non-transitory computer readable storage medium in claim 27, wherein the ectoderm comprises a skin cell, a neuron cell, or a pigment cell.

31. The non-transitory computer readable storage medium in claim 24, wherein predicting the future state of the cell culture comprises predicting the growth of the cells, predicting the total amount of cells, and/or predicting the composition of subpopulations of cells in the cell culture.

32. The non-transitory computer readable storage medium in claim 20, wherein the predicting the future state of the cell culture comprises predicting the state of the cell culture at the next time point an image is captured, at the next two time points an image is capture, and/or at any time point an image is captured.

33. The non-transitory computer readable storage medium in claim 20, wherein the one or more processors further performs:
(b) receiving, by one or more processors, an input of one or more protocol actions for the cell culture;
(c) providing, by the one or more processors, the input of the one or more protocol actions for the cell culture to a machine learning system;
(d) generating, by the machine learning system, a mathematical representation of the one or more protocol actions in combination with the one or more images of the cell culture;
(e) aggregating, by the machine learning system, temporal information based on the mathematical representation of the one or more protocol actions in combination with the one or more images of the cell culture to generate spatio-temporal information;
(f) predicting, by the machine learning system, the yield of the target cell type at the specific time in the future based on the spatio-temporal information; and
(g) sending, by the one or more processors, the yield of the target cell type at the specific time to a communication device,
wherein the communication device is configured to render the target cell type at the specific time on an output device.
